(19) United States
(12) Patent Application Publication
(10) Pub. No.: US 2017/0179221 A1
(43) Pub. Date: Jun. 22, 2017

(54) SEMICONDUCTOR DEVICE AND METHOD FOR PRODUCING THE SAME

(71) Applicant: Renesas Electronics Corporation, Tokyo (JP)

(72) Inventor: Hiroki FUJII, Hitachinaka-shi (JP)

(21) Appl. No.: 15/381,100

(22) Filed: Dec. 15, 2016

(30) Foreign Application Priority Data
Dec. 22, 2015 (JP) 2015-250015

(51) Int. Cl. H01L 29/06; H01L 27/06; H01L 23/522; H03K 17/687; H01L 23/532; H01L 27/092; H01L 29/49; H01L 21/8238; H01L 29/78; H01L 29/10

(52) U.S. Cl. CPC H01L 29/0607; H01L 29/7817; H01L 27/0617; H01L 23/5227; H01L 29/1095; H01L 23/53257; H01L 27/0925; H01L 29/4916; H01L 29/0649; H01L 21/823878; H01L 21/823871; H01L 21/823892; H03K 17/6872

(57) ABSTRACT

A semiconductor device according to one embodiment of the present invention comprises: a semiconductor substrate having a main surface; a noise source element formed at the main surface of the semiconductor substrate; a protection target element formed at the main surface of the semiconductor substrate; an n type region disposed between the noise source element and the protection target element; and a p type region disposed between the noise source element and the protection target element and electrically connected to the n type region. The n type region and the p type region are adjacent to each other on the main surface of the semiconductor substrate in a direction intersecting a direction from the noise source element toward the protection target element.

This nonprovisional application is based on Japanese Patent Application No. 2015-250015 filed on Dec. 22, 2015, with the Japan Patent Office, the entire contents of which are hereby incorporated by reference.

### BACKGROUND OF THE INVENTION

Field of the Invention

The present invention relates to a semiconductor device and its production method.

Description of the Background Art

In a semiconductor device used for an automobile, a motor drive, an audio amplifier, etc., an output transistor and another circuit such as an analog circuit and a logic circuit may be embedded in a single chip. The output transistor and the other circuit are generally formed on a p type substrate. In such a semiconductor device, the drain of the output transistor may have a negative potential due to an inductance load connected to the drain of the output transistor.

When the drain of the output transistor has the negative potential, an electron is injected into the substrate from the drain of the output transistor. The electron injected into the substrate moves via the substrate to a region in which the other circuit is formed. As a result, the electron injected into the substrate may cause an erroneous operation of the other circuit.

In order to prevent the electron injected into the substrate from the drain from affecting the other circuit, a semiconductor device which has an active barrier region at the periphery of a region in which an output transistor is formed is proposed (see Japanese Patent Laying-Open No. 2011-243774 and Japanese Patent Laying-Open No. 2013-247120).

### SUMMARY OF INVENTION

In the active barrier region of the semiconductor device described in each of Japanese Patent Laying-Open No. 2011-243774 and Japanese Patent Laying-Open No. 2013-247120, an n type region and a p type region are aligned in a direction from an outputting element (an emitter region) toward a protection target element (a collector region). Accordingly, the semiconductor devices of the documents have an active barrier region occupying a large area.

The other issues and novel features will be apparent from the description in the specification and the accompanying drawings.

A semiconductor device in one embodiment comprises: a semiconductor substrate having a main surface; a noise source element formed at the main surface of the semiconductor substrate; a protection target element formed at the main surface of the semiconductor substrate; an n type region disposed between the noise source element and the protection target element; and a p type region disposed between the noise source element and the protection target element and electrically connected to the n type region, the n type region and the p type region being adjacent to each other on the main surface of the semiconductor substrate in a direction intersecting a direction from the noise source element toward the protection target element.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram of a semiconductor device according to a first embodiment.

FIG. 2 is a circuit diagram of an input/output circuit in the semiconductor device according to the first embodiment.

FIG. 3 is a top view of the input/output circuit in the semiconductor device according to the first embodiment.

FIG. 4 is a cross section of the semiconductor device according to the first embodiment.

FIG. 5 is a cross section of an active barrier structure in the semiconductor device according to the first embodiment.

FIG. 6 is a top view for illustrating a schematic configuration of the active barrier structure in the semiconductor device according to the first embodiment.

FIG. 7 is a top view showing an exemplary variation of the active barrier structure in the semiconductor device according to the first embodiment.

FIGS. 8A to 8E show a process for producing the semiconductor device according to the first embodiment.

FIG. 9 is a top view of an active barrier structure in a semiconductor device according to a second embodiment.

FIG. 10 is a top view showing a different example of the active barrier structure in the semiconductor device according to the second embodiment.

FIG. 11 is a cross section of the active barrier structure in the semiconductor device according to the second embodiment.

FIGS. 12A to 12E show a process for producing the semiconductor device according to the second embodiment.

FIG. 13 is a top view of an active barrier structure in a semiconductor device according to a third embodiment.

FIG. 14 is a cross section of the active barrier structure in the semiconductor device according to the third embodiment.

FIG. 15 is a top view of an exemplary variation of the active barrier structure in the semiconductor device according to the third embodiment.

FIG. 16 is a cross section of an exemplary variation of the active barrier structure in the semiconductor device according to the third embodiment.

FIGS. 17A to 17D show a process for producing the semiconductor device according to the third embodiment.

FIG. 18 is a top view of an active barrier structure in a semiconductor device according to a fourth embodiment.

FIG. 19 is a cross section of the active barrier structure in the semiconductor device according to the fourth embodiment.

FIGS. 20A to 20E show a process for producing the semiconductor device according to the fourth embodiment.

### DESCRIPTION OF THE PREFERRED EMBODIMENTS

Hereinafter reference will be made to the drawings to describe the present invention in embodiments. In the figures, identical or corresponding components are identically denoted. Furthermore, at least a portion of an embodiment described hereinafter may be combined as desired.

### First Embodiment

(General Structure of Semiconductor Device According to First Embodiment)

Hereinafter, a general structure of a semiconductor device according to a first embodiment will be described with reference to drawings. FIG. 1 is a schematic diagram of a semiconductor device according to the first embodiment. As shown in FIG. 1, the semiconductor device according to the first embodiment has an input/output circuit region IOC, a logic circuit region LGC, a power supply circuit region PWC, an analog circuit region ANC, a predriver circuit region PDC, and a driver circuit region DRC.

A noise source element region is a region in which a semiconductor element which is to be a noise source (i.e., a noise source element) is formed. Input/output circuit region IOC is one example of a noise source element region.

A protection target element region is a region in which a protection target element is formed which requires protection against noise generated in the noise source element region. Logic circuit region LGC, power supply circuit region PWC, analog circuit region ANC, predriver circuit region PDC, and driver circuit region DRC are one example of the protection target element region. Hereinafter, logic circuit region LGC will be described as a specific example of the protection target element region with input/output circuit region IOC as the noise source element region.

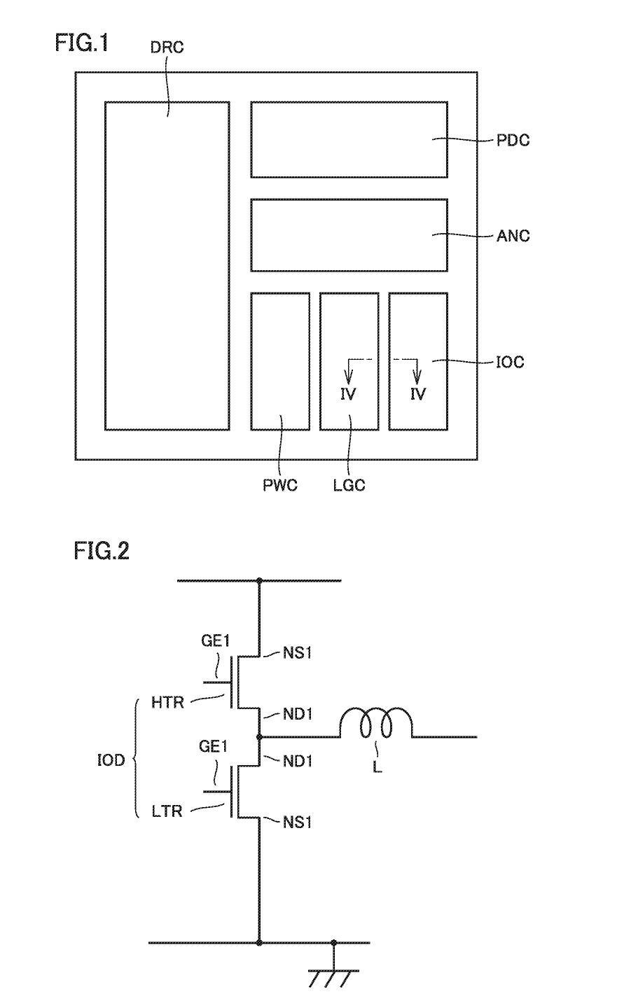

FIG. 2 is a circuit diagram of a noise source element formed in input/output circuit region IOC. As shown in FIG. 2, input/output circuit region IOC has an input/output element which is a noise source element. This input element is a High side LDMOS (Lateral Diffused Metal Oxide Semiconductor) transistor HTR and a Low side LDMOS transistor LTR, for example. An n type drain region ND1 of High side LDMOS transistor HTR and an n type drain region ND1 of Low side LDMOS transistor LTR are each connected to an inductor L, for example. Note that the input/output element is not limited to an LDMOS transistor.

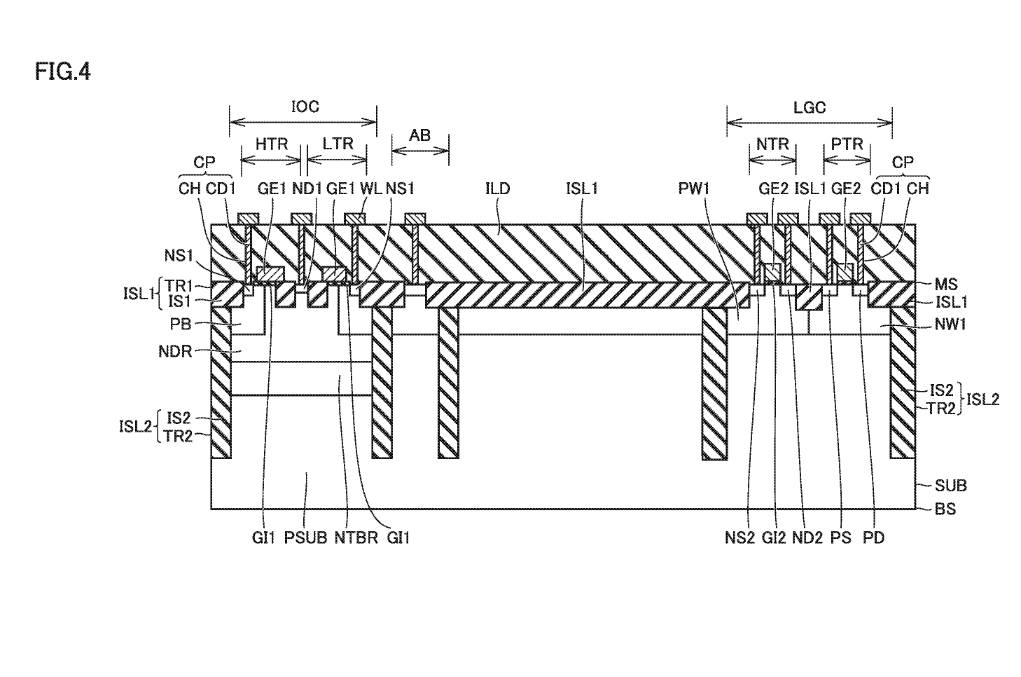

Logic circuit region (protection target element region) LGC shown in FIG. 1 has a protection target element. The protection target element for example has an n type MOS (Metal Oxide Semiconductor) transistor NTR and a p type MOS transistor PTR, as shown in FIG. 4.

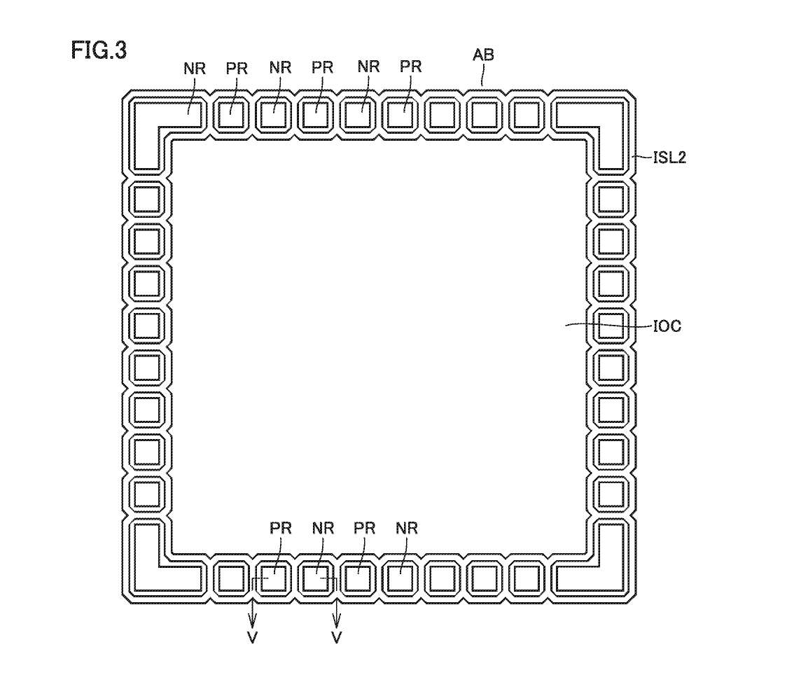

FIG. 3 is a top view showing input/output circuit region IOC (the noise source element region) and an active barrier structure AB which surrounds input/output circuit region IOC. As shown in FIG. 3, the semiconductor device according to the first embodiment has active barrier structure AB. Active barrier structure AB is disposed in the form of a frame (a loop) such that it surrounds input/output circuit region IOC for example. Active barrier structure AB prevents an electron injected from input/output element IOD (the noise source element) of input/output circuit region IOC into semiconductor substrate SUB (see FIG. 3) from reaching a protection target element of logic circuit region LGC. While in the above a configuration has been described in which active barrier structure AB surrounds input/output circuit region (the noise source element region) IOC, active barrier structure AB may be disposed to surround logic circuit region (the protection target element region) LGC.

(Cross Sectional Structure of Semiconductor Device According to First Embodiment)

FIG. 4 is a cross section in a vicinity of active barrier structure AB in the semiconductor device according to the first embodiment. FIG. 4 corresponds to a cross section IV-IV in FIG. 1. As shown in FIG. 4, the semiconductor device according to the first embodiment has semiconductor substrate SUB. Semiconductor substrate SUB has a main surface MS and a back surface BS. Semiconductor substrate SUB is formed for example of single-crystal silicon (Si). Note that semiconductor substrate SUB is set to a ground potential for example.

Hereinafter, a structure of an input/output element which is a noise source element formed in input/output circuit region IOC will be described.

As shown in FIG. 4, semiconductor substrate SUB has a p type substrate region PSUB, an n type buried region NTBR, an n type drift region NDR, a p type body region PB, an n type source region NS1, and an n type drain region ND1. A first element isolation structure ISL1 is formed in main surface MS of semiconductor substrate SUB.

On the side of main surface MS of semiconductor substrate SUB, n type buried region NTBR is disposed in contact with p type substrate region PSUB. An input/output element is formed in this n type buried region NTBR. The input/output element has High side LDMOS transistor HTR and Low side LDMOS transistor LTR, for example.

High side LDMOS transistor HTR has n type drift region NDR, p type body region PB, n type source region NS1, n type drain region ND1, a gate insulating film GI1, and a gate electrode GE1.

N type drift region NDR is disposed on a side of n type buried region NTBR closer to main surface MS. The impurity concentration of n type drift region NDR is preferably lower than the impurity concentration of n type buried region NTBR. P type body region PB is disposed on a side of n type drift region NDR closer to main surface MS in contact with n type drift region NDR. N type source region NS1 is disposed in p type body region PB at main surface MS in contact with p type body region PB. N type drain region ND1 is disposed in n type drift region NDR at main surface MS in contact with n type drift region NDR. N type source region NS1 and n type drain region ND1 have an impurity concentration preferably higher than the impurity concentration of n type drift region NDR.

N type source region NS1 and n type drain region ND1 are spaced from each other. Gate electrode GE1 is disposed on a region between n type source region NS1 and n type drain region ND1 with gate insulating film GI1 interposed. Specifically, gate electrode GE1 is disposed on p type body region PB, n type drift region NDR, and first element isolation structure ISL1.

Low side LDMOS transistor LTR is similar in configuration to High side LDMOS transistor HTR. High side LDMOS transistor HTR and Low side LDMOS transistor LTR share n type drain region ND1 and n type drift region NDR.

Gate insulating film GI1 is formed for example of SiO₂. As gate electrode GE1, polycrystalline silicon having impurity introduced therein for example is used.

First element isolation structure ISL1 has an STI (Shallow Trench Isolation) structure, for example. However, first element isolation structure ISL1 is not limited to this. For example, LOCOS (Local Oxidation of Silicon) may be first element isolation structure ISL1.

First element isolation structure ISL1 is formed on main surface MS at a periphery of n type drain region ND1. First element isolation structure ISL1 has a trench TR1 extending from the main surface MS side toward the back surface BS side, and an insulator IS1 filling trench TR1. Preferably, trench TR1 does not penetrate p type body region PB, and it does not reach n type drift region NDR. As insulator IS1, silicon dioxide (SiO₂) is used, for example.

An interlayer insulating film ILD is formed on High side LDMOS transistor HTR and Low side LDMOS transistor LTR. As interlayer insulating film ILD, BPSG (Boron Phosphorous Silicate Glass) is used, for example. Interlayer insulating film ILD has a flat upper surface.

A contact plug CP is formed in interlayer insulating film ILD. Contact plug CP has a contact hole CH and a conductor CD1. Tungsten (W) is used for conductor CD1, for example. Contact plug CP is connected to n type source region NS1 and n type drain region ND1.

A wiring WL is formed on interlayer insulating film ILD. Wiring WL connects to contact plug CP. Aluminum (Al) is used for wiring WL, for example.

Hereinafter, a structure of logic circuit region LGC as a protection target element region will be described.

As shown in FIG. 4, in logic circuit region LGC, n type MOS transistor NTR and p type MOS transistor PTR as a protection target element are formed.

N type MOS transistor NTR is formed in a p type well PW1. N type MOS transistor NTR has an n type source region NS2, an n type drain region ND2, a gate insulating film GI2, and a gate electrode GE2. P type well PW1 is disposed in p type substrate region PSUB on the main surface MS side in contact with p type substrate region PSUB. N type source region NS2 and n type drain region ND2 are formed in p type well PW1 on the main surface MS side.

Gate insulating film GI2 is formed on main surface MS such that it overlaps p type well PW1 between n type source region NS2 and n type drain region ND2. SiO₂ is used for gate insulating film GI2, for example. Gate electrode GE2 is formed on gate insulating film GI2. For gate electrode GE2, polycrystalline silicon having impurity introduced therein for example is used.

P type MOS transistor PTR has an n type well NW1, a p type source region PS, a p type drain region PD, a gate insulating film GI2, and a gate electrode GE2. P type MOS transistor PTR is similar in structure to n type MOS transistor NTR except that n type well NW1, p type source region PS, and p type drain region PD are opposite in conduction type.

First element isolation structure ISL1 is formed between n type MOS transistor NTR and p type MOS transistor PTR. By first element isolation structure ISL1, n type MOS transistor NTR and p type MOS transistor PTR are electrically insulated and thus isolated from each other.

Interlayer insulating film ILD is formed on n type MOS transistor NTR and p type MOS transistor PTR. Contact plug CP is formed in interlayer insulating film ILD. Contact plug CP is connected to each of n type source region NS2, n type drain region ND2, p type source region PS, and p type drain region PD.

Wiring WL is formed on interlayer insulating film ILD. Wiring WL connects to contact plug CP. Thus, n type MOS transistor NTR and p type MOS transistor PTR are wired.

First element isolation structure ISL1 is formed at a periphery of logic circuit region LGC. A second element isolation structure ISL2 is formed under this first element isolation structure ISL1. Second element isolation structure ISL2 has a DTI (Deep Trench Isolation) structure, for example.

Second element isolation structure ISL2 has a trench TR2 extending from the main surface MS side toward the back surface BS side, and an insulator IS2 filling trench TR2. Trench TR2 preferably penetrates each of p type well PW1 and n type well NW1 and reaches p type substrate region PSUB. SiO₂ is used for insulator IS2, for example.

When second element isolation structure ISL2 is formed, a path from n type drain region ND1 to logic circuit region LGC is longer than when second element isolation structure ISL2 is not formed. Accordingly, there is a higher possibility that if an electron is injected into p type substrate region PSUB from n type drain region ND1, then, before the electron reaches logic circuit region LGC, the electron recombines with a hole in p type substrate region PSUB and disappears. In other words, an erroneous operation of logic circuit region LGC by the electron injected into p type substrate region PSUB from High side LDMOS transistor HTR and Low side LDMOS transistor LTR which are an input/output element, is suppressed. Note that in a plan view, second element isolation structure ISL2 is disposed to surround each of input/output circuit region IOC and logic circuit region LGC.

Hereinafter, a configuration of active barrier structure AB will be described.

As shown in FIG. 4, active barrier structure AB is located at least between input/output circuit region (or noise source element region) IOC and logic circuit region (or protection target element region) LGC. FIG. 5 is a cross section of active barrier structure AB in the semiconductor device according to the first embodiment. FIG. 5 corresponds to a cross section V-V in FIG. 3. As shown in FIG. 5, active barrier structure AB has an n type region NR and a p type region PR.

N type region NR has an n type well NW2 and an n type surface impurity region NSR. N type well NW2 is formed in semiconductor substrate SUB on the main surface MS side. N type surface impurity region NSR is formed in n type well NW2 on the main surface MS side.

P type region PR has a p type well PW2 and a p type surface impurity region PSR. P type region PR is similar in structure to n type region NR except that p type well PW2 and p type surface impurity region PSR are opposite in conduction type.

Interlayer insulating film ILD is formed on n type region NR and p type region PR. Contact plug CP is formed in interlayer insulating film ILD. Contact plug CP connects to n type surface impurity region NSR and p type surface impurity region PSR. Wiring WL is formed on interlayer insulating film ILD. Wiring WL connects to contact plug CP on n type surface impurity region NSR, and contact plug CP on p type surface impurity region PSR. More specifically, n type region NR and p type region PR are short-circuited by contact plug CP and wiring WL.

Active barrier structure AB preferably further has first element isolation structure ISL1 and second element isolation structure ISL2. First element isolation structure ISL1 surrounds each of n type region NR and p type region PR. Second element isolation structure ISL2 is formed under first element isolation structure ISL1.

Preferably, n type region NR has a sidewall impurity region SWR. Sidewall impurity region SWR is formed along a sidewall of second element isolation structure ISL2. Furthermore, sidewall impurity region SWR has a portion which is adjacent to p type substrate region P SUB. The conduction type of sidewall impurity region SWR is the n type. A p type bottom impurity region PBR is formed in contact with a bottom of trench TR2 of second element isolation structure ISL2.

Insulator IS2 of second element isolation structure ISL2 preferably contains an n type impurity. For example, as insulator IS2, PSG (Phosphorus Silicate Glass), BPSG, etc. are preferable. Furthermore, insulator IS2 may contain the n type impurity only in a portion which contacts a surface of trench TR2.

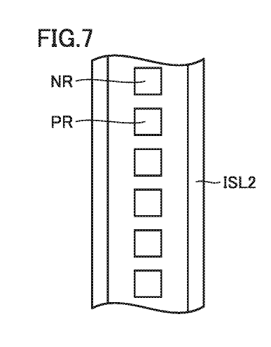

As observed in a direction perpendicular to main surface MS, second element isolation structure ISL2 is formed to surround each of n type region NR and p type region PR. However, how second element isolation structure ISL2 is disposed is not limited thereto. FIG. 7 is a top view showing an exemplary variation of active barrier structure AB in the semiconductor device according to the first embodiment. For example, as shown in FIG. 7, second element isolation structure ISL2 may be formed at a side of n type region NR and p type region PR. In other words, second element isolation structure ISL2 only needs to be formed at the periphery of n type region NR and p type region PR. Second element isolation structure ISL2 penetrates n type well NW2 and reaches p type substrate region PSUB. N type region NR and p type region PR are disposed on main surface MS of semiconductor substrate SUB adjacently and alternately in a direction intersecting a direction from the input/output element or High side LDMOS transistor HTR and Low side LDMOS transistor LTR toward the protection target element or n type MOS transistor NTR and p type MOS transistor PTR, as shown in FIG. 3. Thus, n type region NR and p type region PR, as observed in the direction perpendicular to main surface MS, surround input/output circuit region IOC in one row. Note that n type region NR and p type region PR may surround logic circuit region LGC in one row.

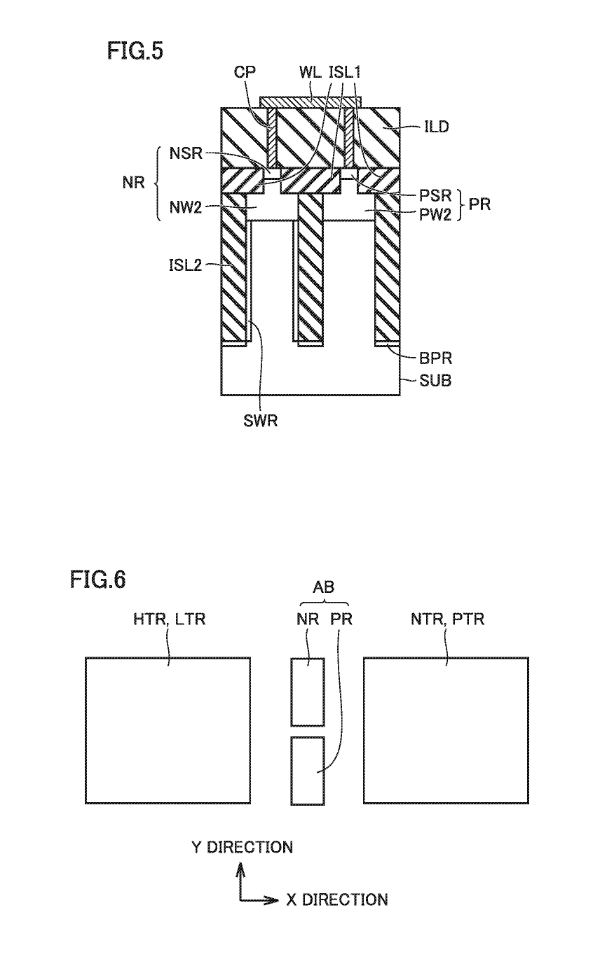

FIG. 6 is a top view for illustrating a schematic configuration of active barrier structure AB in the semiconductor device according to the first embodiment. As shown in FIG. 6, active barrier structure AB in the first embodiment is, as seen in a plan view, disposed between the noise source element, or High side LDMOS transistor HTR and Low side LDMOS transistor LTR, and the protection target element, or n type MOS transistor NTR and p type MOS transistor PTR. A plan view means a point of view at which main surface MS of semiconductor substrate SUB is observed in a direction which is orthogonal to main surface MS.

Active barrier structure AB has n type region NR and p type region PR. N type region NR and p type region PR each have a floating potential. N type region NR and p type region PR are electrically connected to each other.

N type region NR and p type region PR are disposed on main surface MS of the semiconductor substrate adjacently in a direction intersecting a direction from the noise source element, or High side LDMOS transistor HTR and Low side LDMOS transistor LTR, toward the protection target element, or n type MOS transistor NTR and p type MOS transistor PTR (or in a y direction in the figure intersecting an x direction in the figure).

N type region NR and p type region PR are adjacent to each other in a direction (the y direction) for example orthogonal to the x direction. Furthermore, n type region NR and p type region PR are adjacent to each other in a direction (the y direction) inclined relative to the x direction. N type region NR and p type region PR are adjacent to each other in a direction (the y direction) forming an angle equal to or greater than 45 degrees and equal to or less than 90 degrees relative the x direction.

Furthermore, active barrier structure AB may have a single n type region NR and a single p type region PR, or may have a plurality of n type regions NR and a plurality of p type regions PR. Active barrier structure AB is only required to be located between the noise source element and the protection target element, and is only required to surround at least one of the noise source element and the protection target element. Active barrier structure AB may have the plurality of n type regions NR and the plurality of p type regions PR disposed alternately in one row in a plan view to surround at least one of the noise source element and the protection target element.

(Method of Producing Semiconductor Device According to First Embodiment)

Hereinafter, a method of producing the semiconductor device according to the first embodiment will be described. Note that High side LDMOS transistor HTR, Low side LDMOS transistor LTR, n type MOS transistor NTR, and p type MOS transistor PTR are produced in a conventionally generally used method. Accordingly, a process for forming active barrier structure AB will be described below.

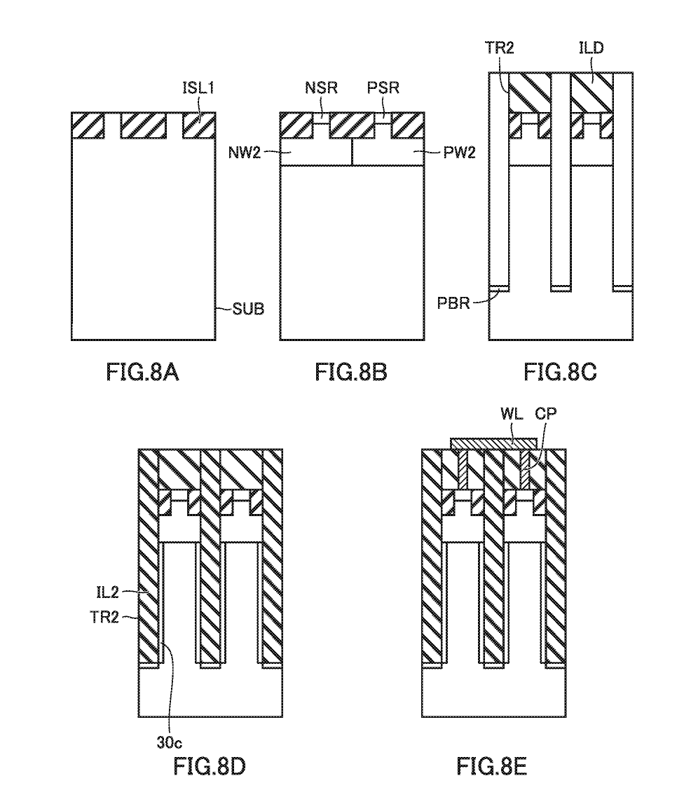

The process for forming active barrier structure AB of the semiconductor device according to the first embodiment has an STI formation step S1, an impurity region formation step S2, a DTI formation step S3, and a wiring step S4. FIG. 8A to FIG. 8E are cross sections of active barrier structure AB in each of these steps.

First, STI formation step S1 is performed. In STI formation step S1, as shown in FIG. 8A, first element isolation structure ISL1 is formed on semiconductor substrate SUB.

In STI formation step S1, trench TR1 is initially formed on main surface MS of semiconductor substrate SUB. Trench TR1 is formed by anisotropic etching, such as RIE (Reactive Ion Etching), for example.

Then, insulator IS1 is deposited on trench TR1. Insulator IS1 is deposited by CVD (Chemical Vapor Deposition), for example. After insulator IS1 is deposited, insulator IS1 is planarized. Such planarization of the insulator is performed by CMP (Chemical Mechanical Polishing), for example. First element isolation structure ISL1 is thus formed.

Secondly, impurity region formation step S2 is performed. In impurity region formation step S2, as shown in FIG. 8B, n type region NR and p type region PR are formed.

N type surface impurity region NSR is formed by performing ion implantation of an n type impurity such as phosphorus (P), for example. P type surface impurity region PSR is formed by performing ion implantation of a p type impurity such as boron (B), for example.

After n type surface impurity region NSR and p type surface impurity region PSR are formed, a heat treatment is performed. By the heat treatment, the n type impurity and the p type impurity are diffused toward the back surface BS side of semiconductor substrate SUB from n type surface impurity region NSR and p type surface impurity region PSR. As a result, n type well NW2 and p type well PW2 are formed.

Thirdly, DTI formation step S3 is performed. In DTI formation step S3, as shown in FIG. 8C and FIG. 8D, interlayer insulating film ILD, p type bottom impurity region PBR, sidewall impurity region SWR, and second element isolation structure ISL2 are formed.

BPSG, etc. are deposited on main surface MS of semiconductor substrate SUB. BPSG, etc. are deposited by CVD, etc., for example. The deposited BPSG, etc. are planarized. SiO₂, etc. are planarized by CMP etc., for example. Interlayer insulating film ILD is thus formed.

A region in which first element isolation structure ISL1 is formed is anisotropically etched by RIE etc. for example. Thus, trench TR2 is formed.

A bottom of trench TR2 is subjected to ion implantation. For the ion implantation, a p type impurity such as boron is used. Thus, p type bottom impurity region PBR is formed.

Trench TR2 is filled with insulator IS2. Filling with insulator IS2 is done by CVD etc., for example. Thus, second element isolation structure ISL2 is formed.

After filling with insulator IS2, a heat treatment is performed. By the heat treatment, the n type impurity included in insulator IS2 is diffused to the semiconductor substrate SUB side. Thus, sidewall impurity region SWR is formed.

Fourthly, wiring step S4 is performed. In wiring step S4, as shown in FIG. 8E, contact plug CP and wiring WL are formed.

Interlayer insulating film ILD is anisotropically etched by RIE etc. Thus, contact hole CH is formed. Contact hole CH is filled with conductor CD1. In interlayer insulating film ILD contact hole CH is formed and contact hole CH is filled with conductor CD1. Filling contact hole CH with conductor CD1 is done by CVD etc., for example. Thus, contact plug CP is formed.

An aluminum layer is formed on interlayer insulating film ILD. The aluminum layer is formed by sputtering etc., for example. The aluminum layer is patterned. The aluminum layer is patterned using photolithography, etching, etc. Wiring WL is thus formed.

(Operation of Semiconductor Device According to First Embodiment)

Hereinafter, an operation of the semiconductor device according to the first embodiment will be described with reference to the drawings.

When High side LDMOS transistor HTR or Low side LDMOS transistor LTR switches from the ON state to the OFF state, a current which was flowing in the ON state is interrupted. On this occasion, by inductor L, counter electromotive force is generated in n type drain region ND1. In other words, a negative potential is applied to n type drain region ND1.

By the application of the negative potential, a pn junction between n type drain region ND1 and semiconductor substrate SUB is forward-biased. As a result, an electron in n type drain region ND1 is injected into p type substrate region PSUB.

N type drain region ND1 has the n conduction type, semiconductor substrate SUB has the p conduction type, and n type region NR has the n conduction type. More specifically, a bipolar transistor is formed which has n type drain region ND1 as an emitter, p type substrate region PSUB as a base, and n type region NR as a collector. Accordingly, by a bipolar effect, an electron injected into p type substrate region PSUB from n type drain region ND1 flows into n type region NR.

N type region NR and p type region PR are short-circuited by contact plug CP and wiring WL. Accordingly, the electron which has flowed into n type region NR extracts a hole in p type region PR. P type region PR having the hole extracted therefrom is decreased in potential. More specifically, a potential barrier is formed directly under p type region PR. Accordingly, the electron injected into p type substrate region PSUB from n type drain region ND1 less easily passes through the region directly under p type region PR.

(Effect According to First Embodiment)

The first embodiment provides a semiconductor device including active barrier structure AB having n type region NR and p type region PR disposed on main surface MS adjacently in a direction intersecting a direction from the input/output element, or High side LDMOS transistor HTR and Low side LDMOS transistor LTR, toward the protection target element, or n type MOS transistor NTR and p type MOS transistor PTR. Accordingly, active barrier structure AB according to the first embodiment occupies a small area. Accordingly, the semiconductor device according to the first embodiment can suppress noise transmission from the noise source element region to the protection target element region despite the small area.

When sidewall impurity region SWR is formed, n type region NR extends from the main surface MS side toward the back surface BS side to a position which reaches p type substrate region PSUB. Accordingly, an electron injected into p type substrate region PSUB from n type drain region ND1 easily flows into n type region NR. As a result, noise transmission from the noise source element region to the protection target element region is further suppressed.

When insulator IS2 filling trench TR2 of second element isolation structure ISL2 contains an n type impurity, it is possible to form sidewall impurity region SWR only by a heat treatment. Accordingly, a mask for forming sidewall impurity region SWR by ion implantation is unnecessary. In other words, the production process can be simplified.

(Semiconductor Device According to Second Embodiment)

Hereinafter, a second embodiment will be described with reference to the drawings. Herein, a point different from the first embodiment will mainly be described.

(Structure of Semiconductor Device According to Second Embodiment)

The second embodiment provides a semiconductor device which, as well as that of the first embodiment, has input/output circuit region IOC which is a noise source element region, logic circuit region LGC which is a protection target element region, and active barrier structure AB.

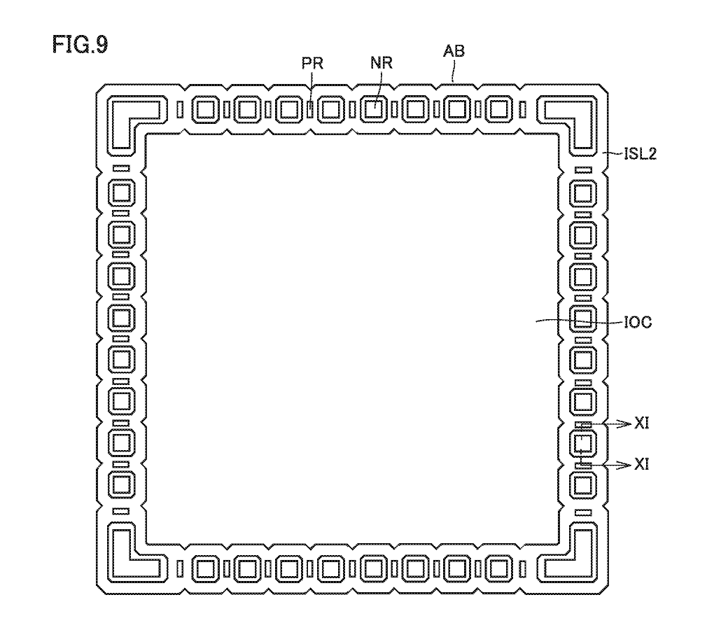

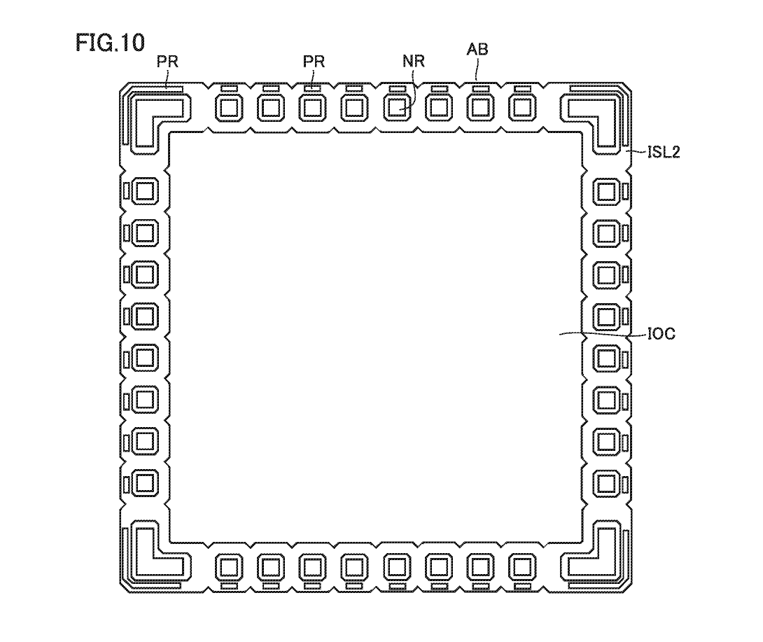

FIG. 9 is a top view of a structure in a vicinity of active barrier structure AB. FIG. 10 is a top view showing a different example of a structure in a vicinity of active barrier structure AB. As shown in FIG. 9, active barrier structure AB, as well as that of the semiconductor device according to the first embodiment, has n type region NR and p type region PR. N type region NR and p type region PR are, as well as those of the semiconductor device of the first embodiment, disposed on main surface MS adjacently in a direction from the input/output element, or High side LDMOS transistor HTR and Low side LDMOS transistor LTR, toward the protection target element, or n type MOS transistor NTR and p type MOS transistor PTR. Thus, n type region NR and p type region PR surround input/output circuit region IOC in one row. Note that n type region NR and p type region PR may surround logic circuit region LGC in one row.

The semiconductor device according to the second embodiment may not have n type region NR and p type region PR alternately disposed to surround input/output circuit region IOC in one row. For example, as shown in FIG. 10, n type region NR may be disposed to surround input/output circuit region IOC in one row and p type region PR may be disposed at a side of n type region NR.

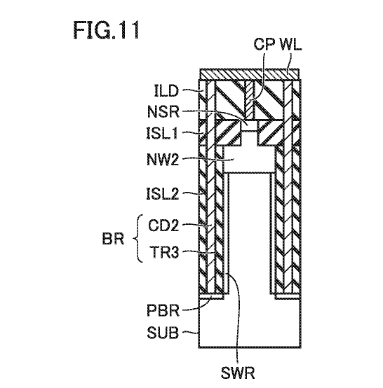

FIG. 11 is a cross section in a vicinity of active barrier structure AB of the semiconductor device according to the second embodiment. FIG. 11 corresponds to a cross section XI-XI in FIG. 9. As shown in FIG. 11, n type region NR has n type surface impurity region NSR and n type well NW2. N type region NR may have sidewall impurity region SWR.

N type region NR is surrounded by second element isolation structure ISL2, as shown in FIG. 9. Sidewall impurity region SWR is disposed along a sidewall of second element isolation structure ISL2 and also has a portion which is adjacent to p type substrate region P SUB.

As shown in FIG. 11, p type region PR has p type bottom impurity region PBR and a buried region BR. Buried region BR is formed in second element isolation structure ISL2. Buried region BR has a trench TR3 and a conductor CD2 filling trench TR3.

Trench TR3 extends through second element isolation structure ISL2 from main surface MS of semiconductor substrate SUB to a surface of p type bottom impurity region PBR. As conductor CD2, polycrystalline silicon, tungsten, etc. are used, for example.

Buried region BR connects to p type bottom impurity region PBR. Furthermore, buried region BR is connected to n type region NR by contact plug CP and wiring WL. Accordingly, p type bottom impurity region PBR is short-circuited with n type region NR.

Note that while in the above, n type region NR is formed by n type surface impurity region NSR and n type well NW2 and p type region PR is formed by p type bottom impurity region PBR and buried region BR, n type region NR may be formed by n type bottom impurity region NBR and buried region BR and p type region PR may be formed by p type surface impurity region PSR and p type well PW2.

(Method of Producing Semiconductor Device According to Second Embodiment)

Hereinafter, a method of producing the semiconductor device according to the second embodiment will be described. As well as the semiconductor device production method according to the first embodiment, the semiconductor device production method according to the second embodiment will be described with a method of producing active barrier structure AB focused on.

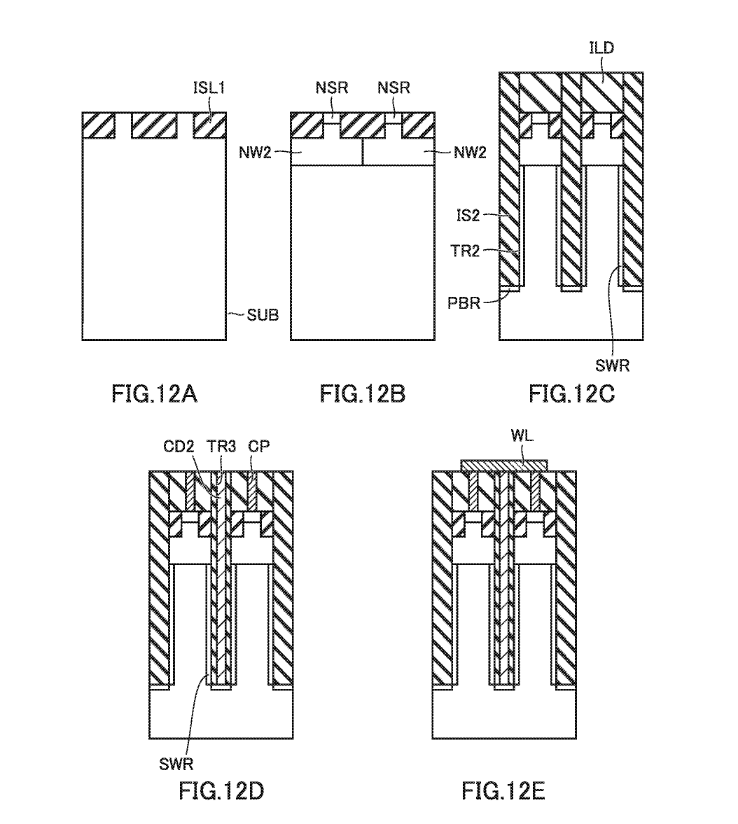

The process for forming active barrier structure AB of the semiconductor device according to the second embodiment has an STI formation step S5, an impurity region formation step S6, a DTI formation step S7, and a buried region formation step S8 and a wiring step S9. FIG. 12A to FIG. 12E are cross sections of active barrier structure AB of the semiconductor device according to the second embodiment in each of these steps.

First, STI formation step S5 is performed. STI formation step S5 is similar to STI formation step S1 of the first embodiment. In STI formation step S5, as shown in FIG. 12A, first element isolation structure ISL1 is formed.

Secondly, impurity region formation step S6 is performed. In impurity region formation step S6, as shown in FIG. 12B, n type region NR is formed. Impurity region formation step S6 is basically similar to impurity region formation step S2 in the first embodiment. However, in the second embodiment, p type region PR is not formed in impurity region formation step S6.

Thirdly, DTI formation step S7 is performed. DTI formation step S7 is similar to DTI formation step S3 in the active barrier structure formation process for the semiconductor device according to the first embodiment. In DTI formation step S7, interlayer insulating film ILD, second element isolation structure ISL2 and p type bottom impurity region PBR shown in FIG. 12C are formed.

Fourthly, buried region formation step S8 is performed. In buried region formation step S8, as shown in FIG. 12D, buried region BR and contact plug CP are formed.

In buried region formation step S8, trench TR3 is initially formed in second element isolation structure ISL2. Trench TR3 is formed for example by anisotropic etching such as RIE. By forming trench TR3, p type bottom impurity region PBR is exposed. Note that, by the anisotropic etching in forming trench TR3, contact hole CH is formed in interlayer insulating film ILD. Subsequently, trench TR3 and contact hole CH are filled with conductor CD2 and conductor CD1. Filling with conductor CD2 and conductor CD1 is done by CVD etc., for example. Thus, buried region BR and contact plug CP are formed.

Fifthly, wiring step S9 is performed. In wiring step S9, as shown in FIG. 12E, wiring WL is formed. Wiring WL is formed by forming and patterning an aluminum layer. The aluminum layer is formed by sputtering etc., for example. The aluminum layer is patterned using photolithography, etching, etc.

(Operation of Semiconductor Device According to Second Embodiment)

An operation of the semiconductor device according to the second embodiment is similar to an operation of the semiconductor device according to the first embodiment. In other words, an electron injected into p type substrate region PSUB from n type drain region ND1 of High side LDMOS transistor HTR and Low side LDMOS transistor LTR flows into n type region NR. N type region NR extracts a hole from p type bottom impurity region PBR of p type region PR. Thus, a potential barrier is formed directly under p type bottom impurity region PBR. Thus, the electron injected into p type substrate region PSUB from n type drain region ND1 less easily passes through a region directly under p type region PR.

(Effect of Semiconductor Device According to Second Embodiment)

Active barrier structure AB of the semiconductor device according to the second embodiment has a potential barrier formed under p type bottom impurity region PBR. Accordingly, as compared with the semiconductor device according to the first embodiment, the potential barrier is formed in semiconductor substrate SUB at a deeper position. Accordingly, in the semiconductor device according to the second embodiment, the electron injected into p type substrate region PSUB from n type drain region ND1 further less easily passes through the region directly under p type region PR. As a result, the semiconductor device according to the second embodiment can more suppress noise transmission from the noise source element region to the protection target element region.

(Semiconductor Device According to Third Embodiment)

Hereinafter, a third embodiment will be described with reference to the drawings. Herein, a point different from the first embodiment will mainly be described.

(Structure of Semiconductor Device According to Third Embodiment)

The third embodiment provides a semiconductor device which, as well as that of the first embodiment, has input/output circuit region IOC which is a noise source element region, logic circuit region LGC which is a protection target element region, and active barrier structure AB.

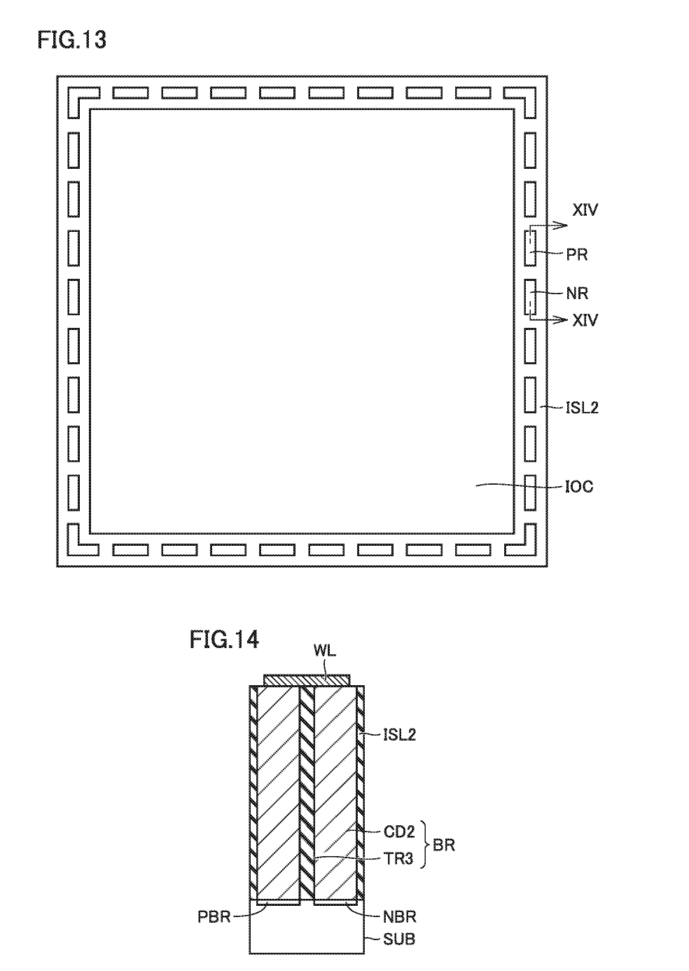

FIG. 13 is a top view showing a structure in a vicinity of active barrier structure AB of a semiconductor device according to the third embodiment. FIG. 14 is a cross section showing a structure in a vicinity of active barrier structure AB of the semiconductor device according to the third embodiment. As shown in FIG. 13, active barrier structure AB has n type region NR, p type region PR, and second element isolation structure ISL2. N type region NR and p type region PR are disposed on main surface MS alternately in a direction intersecting a direction from the input/output element, or High side LDMOS transistor HTR and Low side LDMOS transistor LTR, toward the protection target element, or n type MOS transistor NTR and p type MOS transistor PTR. Thus, n type region NR and p type region PR surround input/output circuit region IOC in one row. Note that n type region NR and p type region PR may surround logic circuit region LGC in one row.

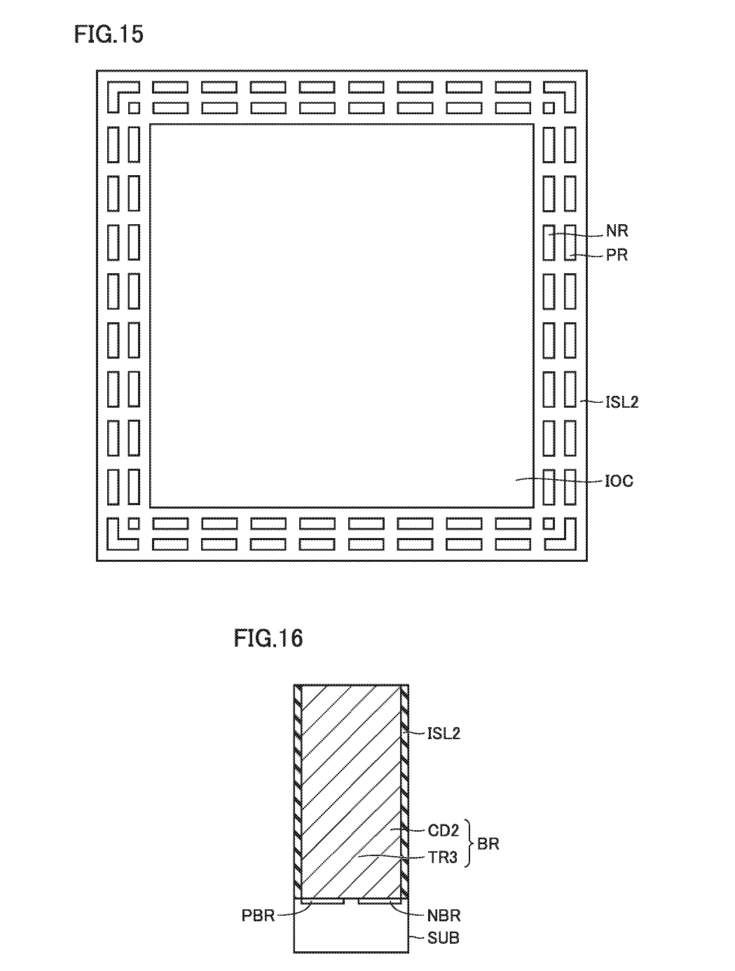

However, it is not essential to dispose n type region NR and p type region PR in this manner. FIG. 15 is a top view showing an exemplary variation of the structure in a vicinity of active barrier structure AB. As shown in FIG. 15, for example, n type region NR may be disposed closer to input/output circuit region IOC, and p type region PR may be disposed outer than n type region NR. In other words, input/output circuit region IOC may be surrounded by n type region NR and p type region PR in two rows.

As shown in FIG. 14, n type region NR and p type region PR are formed in second element isolation structure ISL2. N type region NR has n type bottom impurity region NBR and buried region BR. P type region PR has p type bottom impurity region PBR and buried region BR.

N type bottom impurity region NBR and p type bottom impurity region PBR are connected to each other by buried region BR and wiring WL. Accordingly, n type bottom impurity region NBR and p type bottom impurity region PBR are short-circuited.

While in FIG. 14, buried region BR is provided to correspond to each of n type bottom impurity region NBR and p type bottom impurity region PBR, this is not exclusive. FIG. 16 is a cross section showing an exemplary variation of a structure in a vicinity of active barrier structure AB. As shown in FIG. 16, a single buried region BR may be formed to correspond to n type bottom impurity region NBR and p type bottom impurity region PBR. By such a configuration, n type bottom impurity region NBR and p type bottom impurity region PBR may be short-circuited.

(Operation of Semiconductor Device According to Third Embodiment)

An operation of the semiconductor device according to the third embodiment is similar to an operation of the semiconductor device according to the first embodiment. Initially, an electron injected into p type substrate region PSUB from High side LDMOS transistor HTR and Low side LDMOS transistor LTR flows into n type bottom impurity region NBR. N type bottom impurity region NBR is short-circuited with p type bottom impurity region PBR. Accordingly, the electron having flowed into n type bottom impurity region NBR extracts a hole from p type bottom impurity region PBR and decreases the potential of p type bottom impurity region PBR. As a result, a potential barrier is formed under the p type region. Thus, the electron injected into p type substrate region PSUB from n type drain region ND1 less easily passes through a region directly under p type region PR.

(Method of Producing Semiconductor Device According to Third Embodiment)

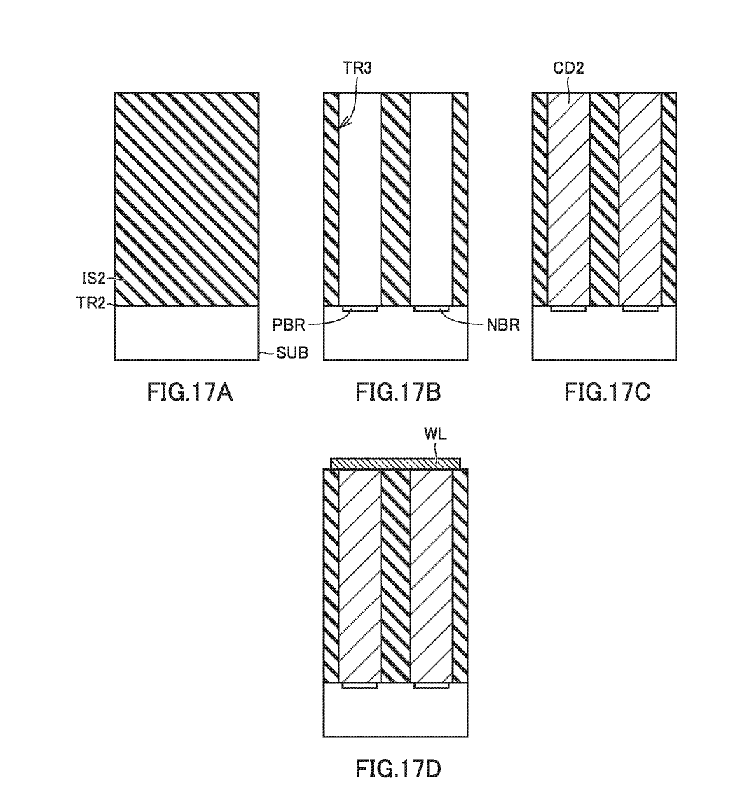

Hereinafter, a method of producing the semiconductor device according to the third embodiment will be described. As well as the semiconductor device production method according to the first embodiment, the semiconductor device production method according to the third embodiment will be described with a method of producing active barrier structure AB focused on. FIG. 17A to FIG. 17D are cross sections of active barrier structure AB of the semiconductor device according to the third embodiment in each of these steps.

The process for forming active barrier structure AB of the semiconductor device according to the third embodiment has an DTI formation step S10, a bottom impurity region formation step S11, a buried region formation step S12, and a wiring step S13.

First, DTI formation step S10 is performed. In DTI formation step S10, as shown in FIG. 17A, second element isolation structure ISL2 is formed.

In DTI formation step S10, second element isolation structure ISL2 is formed. In DTI formation step S10, trench TR2 is initially formed by anisotropically etching semiconductor substrate SUB. Subsequently, trench TR2 is filled with insulator IS2.

Secondly, bottom impurity region formation step Sll is performed. In bottom impurity region formation step S11, as shown in FIG. 17B, n type bottom impurity region NBR and p type bottom impurity region PBR are formed.

In bottom impurity region formation step S11, trench TR3 is initially formed. Trench TR3 is formed by subjecting second element isolation structure ISL2 to RIE or similar anisotropic etching to expose semiconductor substrate SUB.

Subsequently, n type bottom impurity region NBR and p type bottom impurity region PBR are formed. N type bottom impurity region NBR is formed by ion-implanting an n type impurity such as phosphorus into a bottom of trench TR3 of a portion that will serve as n type region NR. In doing so, trench TR3 that will serve as p type region PR is masked to prevent ion implantation of the n type impurity thereinto.

P type bottom impurity region PBR is formed by ion-implanting a p type impurity such as boron into a bottom of trench TR3 that will serve as p type region PR. In doing so, trench TR3 that will serve as n type region NR is masked to prevent ion implantation of the p type impurity thereinto.

Thirdly, buried region formation step S12 is performed. In buried region formation step S12, as shown in FIG. 17C, buried region BR is formed. Buried region BR is formed by filling trench TR3 with conductor CD2. Filling with conductor CD2 is done by CVD etc., for example.

Fourthly, wiring step S13 is performed. In wiring step S13, as shown in FIG. 17D, wiring WL is formed. Wiring WL is formed by forming and patterning an aluminum layer. The aluminum layer is formed by sputtering etc., for example. The aluminum layer is patterned using photolithography, etching, etc.

(Effect of Semiconductor Device According to Third Embodiment)

Active barrier structure AB of the semiconductor device according to the third embodiment has n type bottom impurity region NBR in semiconductor substrate SUB at a deep position. Accordingly, an electron injected into p type substrate region PSUB from n type drain region ND1 more easily flows into n type region NR.

Furthermore, active barrier structure AB of the semiconductor device according to the third embodiment has p type bottom impurity region PBR in semiconductor substrate SUB at a deep position. Accordingly, a potential barrier is formed in semiconductor substrate SUB at a deeper position. As a result of these, in the semiconductor device according to the third embodiment, the electron injected into p type substrate region PSUB from n type drain region ND1 further less easily passes through the region directly under active barrier structure AB.

Furthermore, active barrier structure AB of the semiconductor device in the third embodiment has n type region NR and p type region PR formed using buried region BR, and accordingly, having a small resistance value. Accordingly, if n type region NR and p type region PR are each reduced in size, the function of active barrier structure AB can still be maintained. In other words, active barrier structure AB of the semiconductor device according to the third embodiment can occupy a reduced area.

### Fourth Embodiment

Hereinafter, a fourth embodiment will be described with reference to the drawings. Herein, a point different from the first embodiment will mainly be described.

The fourth embodiment provides a semiconductor device which, as well as that of the first embodiment, has input/output circuit region IOC which is a noise source element region, logic circuit region LGC which is a protection target element region, and active barrier structure AB.

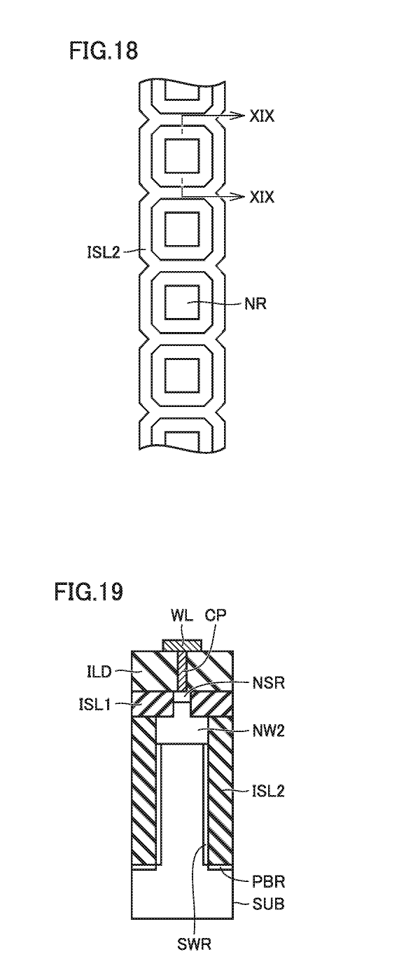

FIG. 18 is a top view showing a structure in a vicinity of active barrier structure AB of the semiconductor device according to the fourth embodiment. FIG. 19 is a cross section showing a structure in a vicinity of active barrier structure AB of the semiconductor device according to the fourth embodiment. FIG. 19 corresponds to a cross section XIX-XIX in FIG. 18. As shown in FIG. 18, active barrier structure AB has n type region NR and second element isolation structure ISL2. In contrast to active barrier structure AB of the semiconductor device according to the first embodiment, active barrier structure AB of the semiconductor device according to the fourth embodiment does not have p type region PR.

N type region NR surrounds input/output circuit region IOC in one row. Note that n type region NR may surround logic circuit region LGC in one row. As shown in FIG. 19, n type region NR has n type well NW2, n type surface impurity region NSR, and sidewall impurity region SWR.

Second element isolation structure ISL2 is formed to surround each n type region NR. However, how second element isolation structure ISL2 is disposed is not limited thereto. For example, second element isolation structure ISL2 may be formed at a side of n type region NR. In other words, second element isolation structure ISL2 only needs to be formed at a periphery of n type region NR. Insulator IS2 of second element isolation structure ISL2 preferably contains an n type impurity. For example, as insulator IS2, PSG (Phosphorus Silicate Glass), BPSG, etc. are preferable. Furthermore, insulator IS2 may contain the n type impurity only in a portion which contacts a surface of trench TR2.

Interlayer insulating film ILD is formed on n type region NR. Contact plug CP is formed in interlayer insulating film ILD. Contact plug CP connects to n type surface impurity region NSR. Wiring WL is formed on interlayer insulating film ILD. Wiring WL connects to contact plug CP on n type surface impurity region NSR. Wiring WL is fixed to a potential equal to or greater than 0 V. For example wiring WL is grounded.

(Method of Producing Semiconductor Device According to Fourth Embodiment)

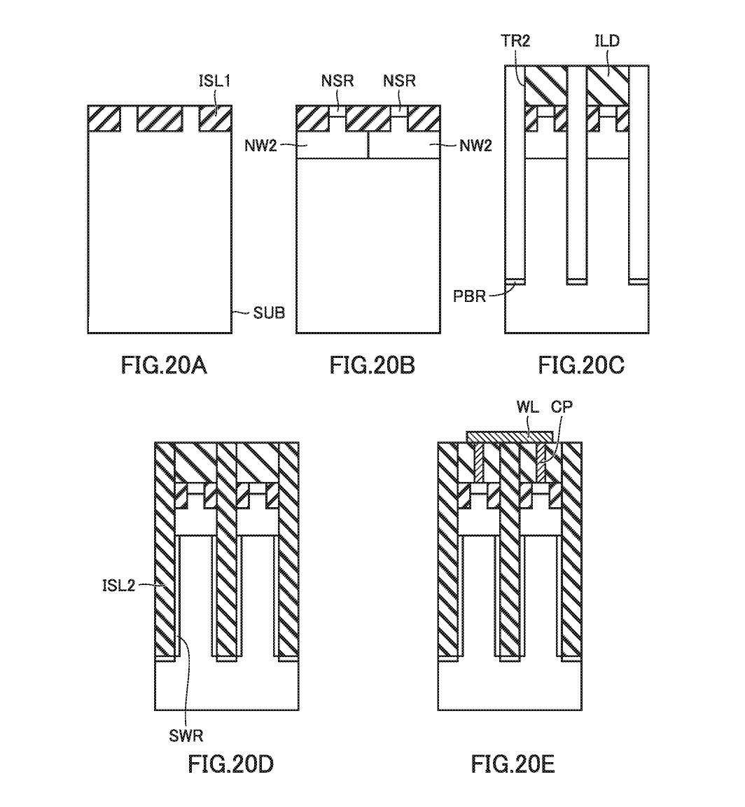

A process for forming active barrier structure AB of the semiconductor device according to the fourth embodiment has an STI formation step S13, an impurity region formation step S14, a DTI formation step S15, and a wiring step S16. FIG. 20A to FIG. 20E are cross sections of active barrier structure AB of the semiconductor device according to the fourth embodiment in each of these steps.

First, STI formation step S13 is performed. STI formation step S13 is similar to STI formation step S1 of the first embodiment. In STI formation step S13, as shown in FIG. 20A, first element isolation structure ISL1 is formed.

Secondly, impurity region formation step S14 is performed. In impurity region formation step S14, as shown in FIG. 20B, n type region NR is formed. Impurity region formation step S14 is basically similar to impurity region formation step S2 in the first embodiment. However, in the fourth embodiment, p type region PR is not formed in impurity region formation step S14.

Thirdly, DTI formation step S15 is performed. DTI formation step S15 is similar to DTI formation step S3 in the active barrier structure formation process for the semiconductor device according to the first embodiment. In DTI formation step S15, as shown in FIGS. 20C and 20D, interlayer insulating film ILD, second element isolation structure ISL2, p type bottom impurity region PBR, and sidewall impurity region SWR are formed.

Fourthly, wiring step S16 is performed. Wiring step S16 is similar to wiring step S4 in the first embodiment. In wiring step S16, as shown in FIG. 20E, contact plug CP and wiring WL are formed.

(Operation of Semiconductor Device According to Fourth Embodiment)

N type region NR is grounded. On the other hand, n type drain region ND1 has a negative potential because of an effect of counter-electromotive force. Accordingly, an electron injected into p type substrate region PSUB from High side LDMOS transistor HTR and Low side LDMOS transistor LTR flows into n type region NR having high potential. As a result, the electron injected into p type substrate region PSUB from n type drain region ND1 less easily passes through the region directly under p type region PR.

(Effect of Semiconductor Device According to Fourth Embodiment)

Active barrier structure AB of the semiconductor device according to the fourth embodiment has sidewall impurity region SWR, and accordingly, n type region NR extends in semiconductor substrate SUB to a deep position. Accordingly, an electron injected into p type substrate region PSUB from n type drain region ND1 easily flows into n type region NR. As a result, even without p type region PR, noise transmission from input/output circuit region IOC to logic circuit region LGC which is the protection target element region can be suppressed.

And active barrier structure AB of the semiconductor device according to the fourth embodiment has n type region NR disposed in one row. Accordingly, active barrier structure AB occupies a small area. Accordingly, the semiconductor device according to the fourth embodiment can suppress noise transmission from the noise source element region to the protection target element region despite the small occupied area.

When insulator IS2 filling trench TR2 of second element isolation structure ISL2 contains an n type impurity, it is possible to form sidewall impurity region SWR only by a heat treatment. Accordingly, a mask for forming sidewall impurity region SWR by ion implantation is unnecessary. In other words, the production process can be simplified.

While the present invention has been described in embodiments, it should be understood that the embodiments disclosed herein are illustrative and non-restrictive in any respect. The scope of the present invention is defined by the terms of the claims, and is intended to include any modifications within the meaning and scope equivalent to the terms of the claims.

What is claimed is:

1. A semiconductor device comprising:
a semiconductor substrate having a main surface;
a noise source element formed at the main surface of the semiconductor substrate;
a protection target element formed at the main surface of the semiconductor substrate;
an n type region disposed between the noise source element and the protection target element; and
a p type region disposed between the noise source element and the protection target element and electrically connected to the n type region,
the n type region and the p type region being adjacent to each other on the main surface of the semiconductor device in a direction intersecting a direction from the noise source element toward the protection target element.

2. The semiconductor device according to claim 1, wherein the n type region and the p type region are alternately disposed in a plan view to surround one of the noise source element and the protection target element in one row.

3. The semiconductor device according to claim 1, wherein:
the semiconductor substrate has a substrate region and a well region formed on the substrate region;
in the main surface of the semiconductor substrate, a trench is formed to penetrate the well region to reach the substrate region; and
the trench is disposed at a periphery of the n type region and the p type region.

4. The semiconductor device according to claim 3, wherein the n type region is disposed along a sidewall of the trench and also includes a portion which is adjacent to the substrate region.

5. A semiconductor device comprising:
a semiconductor substrate having a main surface;
a substrate region formed at the semiconductor substrate;
a well region formed on the substrate region;
a noise source element formed at the main surface of the semiconductor substrate;
a protection target element formed at the main surface of the semiconductor substrate;
an n type region disposed between the noise source element and the protection target element; and
a p type region disposed between the noise source element and the protection target element and electrically connected to the n type region,
in the main surface of the semiconductor substrate, a trench being formed to penetrate the well region to reach the substrate region,
at least one impurity region of the n type region and the p type region being disposed at a bottom of the trench.

6. The semiconductor device according to claim 5, further comprising a conductor disposed in the trench and electrically connected to the one impurity region.

7. The semiconductor device according to claim 5, wherein the n type region and the p type region surround one of the noise source element and the protection target element.

8. The semiconductor device according to claim 5, wherein the n type region and the p type region are alternately disposed in a plan view to surround one of the noise source element and the protection target element in one row.

9. A semiconductor device comprising:
a semiconductor substrate having a main surface;
a p type substrate region formed at the semiconductor substrate;
an n type well region formed on the substrate region;
a noise source element formed at the main surface of the semiconductor substrate;
a protection target element formed at the main surface of the semiconductor substrate; and
an n type region disposed between the noise source element and the protection target element and fixed to a potential equal to or greater than 0 V,
in the main surface of the semiconductor substrate, a trench being formed to penetrate the well region to reach the substrate region,
the n type region being disposed along a sidewall of the trench and also including a portion which is adjacent to the substrate region.

10. The semiconductor device according to claim 9, wherein the n type region surrounds one of the noise source element and the protection target element.

11. The semiconductor device according to claim 10, wherein an insulator containing an n type impurity is formed on a surface of the trench.

12. A semiconductor device production method comprising:
forming an n type region and a p type region at a semiconductor substrate having a main surface and having a substrate region and a well region formed on the substrate region;
forming at a periphery of the n type region and the p type region a trench penetrating the substrate region to reach the well region;
forming on a surface of the trench an insulator containing an n type impurity; and
subjecting the insulator to a heat treatment.
